(19) United States
(12) Patent Application Publication
(10) Pub. No.: US 2016/0017197 A1
(43) Pub. Date: Jan. 21, 2016

(54) ELEMENT SEALING RESIN COMPOSITION FOR ORGANIC ELECTRONIC DEVICE, ELEMENT SEALING RESIN SHEET FOR ORGANIC ELECTRONIC DEVICE, ORGANIC ELECTROLUMINESCENCE ELEMENT, AND IMAGE DISPLAY

(71) Applicant: FURUKAWA ELECTRIC CO., LTD., Tokyo (JP)

(72) Inventors: Tetsuya MIEDA, Tokyo (JP); Toshimitsu NAKAMURA, Tokyo (JP); Kunihiko ISHIGURO, Tokyo (JP); Masami AOYAMA, Tokyo (JP)

(73) Assignee: FURUKAWA ELECTRIC CO., LTD., Tokyo (JP)

(21) Appl. No.: 14/866,802

(22) Filed: Sep. 25, 2015

Related U.S. Application Data
(63) Continuation of application No. PCT/JP2014/052843, filed on Feb. 7, 2014.

(30) Foreign Application Priority Data
Mar. 27, 2013 (JP) 2013-067056

(51) Int. Cl. C09K 3/10; H01L 51/00

(52) U.S. Cl. CPC C09K 3/10; H01L 51/004; C09K 2200/0617; C09K 2200/0247; C09K 2200/0239; C09K 2200/04; H01L 51/5237

(57) ABSTRACT

Provided are an element sealing resin composition for organic electronic devices, which promotes a balance between the water vapor barrier properties and adhesiveness, decreases the water content, and sufficiently suppresses the generation of outgases, so that consequently the service life of an element for organic electronic devices can be lengthened, and which gives a satisfactory external appearance when used to seal an organic electronic device; an element sealing resin sheet for organic electronic devices; an organic electroluminescent element; and an image display apparatus. Disclosed is an element sealing resin composition for organic electronic devices, comprising a polyisobutylene resin (A) having a weight average molecular weight (Mw) of 10,000 to 300,000 and a hydrogenated cyclic olefin-based polymer (B), and having a water content according to the Karl-Fischer method of 500 ppm or less and an amount of outgas generation of 500 ppm or less when heated at 85° C. for 1 hour.

### TECHNICAL FIELD

The present invention relates to an element sealing resin composition for organic electronic devices used to seal an element for organic electronic devices, an element sealing resin sheet for organic electronic devices, an organic electroluminescent element, and an image display apparatus.

### BACKGROUND ART

In recent years, research on various organic electronic devices such as organic electroluminescent (hereinafter, may also be referred to as “organic EL”) displays, organic EL lightings, and organic semiconductors and organic solar cells has been actively conducted, and these devices are expected to serve as the next-generation displays that will replace liquid crystal displays (LCD's), or as the next-generation lightings that will replace light emitting diode (LED) lightings. Furthermore, since organic EL elements are such that all of the constituent elements thereof can be formed from solid materials, there is a possibility that organic EL elements may be used as flexible displays or lightings. Organic EL elements are basically configured to include a transparent ITO (indium tin oxide) electrode (anode), an organic film (organic hole transport layer, organic light emitting layer, or the like), and a metal electrode (cathode) formed on a glass substrate, and the organic EL element becomes self-luminous as electricity is caused to flow between the anode layer and the cathode layer.

However, in regard to organic EL elements, it is known that the organic films or the metal electrodes are vulnerable to moisture and organic gases generated from the constituent members (hereinafter, also referred to as “outgases”).

Thus, for the purpose of lengthening the service life of organic EL elements, attempts have been made to prevent deterioration of organic EL elements by storing the organic EL elements in an atmosphere free from moisture or reducing the outgases from the constituent members as much as possible.

For example, as a technique for maintaining an atmosphere free from moisture, a sealing composition containing a hydrogenated cyclic olefin-based polymer and a polyisobutylene resin having a weight average molecular weight of more than 500,000 has been suggested (see, for example, Patent Document 1). Furthermore, there has been suggested an adhesive composition having excellent peeling strength, in which the water vapor barrier properties are suppressed to a lower level by selecting a polyisobutylene resin having a lower molecular weight such as a viscosity average molecular weight (Mv) of from 300,000 to 500,000, in consideration of preventing a decrease in peeling strength (see, for example, Patent Document 2).

### CITATION LIST

### Patent Document

Patent Document 1: JP 5074423 B

Patent Document 2: JP 2012-193335 A

### DISCLOSURE OF THE INVENTION

### Problem to be Solved by the Invention

However, in the inventions described in Patent Documents 1 and 2, although the water vapor barrier properties are high, in a case in which the water content or the amount of outgas generation is large, deterioration of elements for organic electronic devices could not be prevented. Furthermore, since the adhesive force to an adherend is not sufficient, consequently there have been limitations on the lengthening of the service life of elements for organic electronic devices. Furthermore, in the inventions described in patent Documents 1 and 2, since the conformity to an adherend is poor, there has been a problem that air bubbles enter between the sealing composition and the adherend when used for sealing, and the external appearance is impaired.

Thus, it is an object of the present invention to provide an element sealing resin composition for organic electronic devices, which promotes a balance between the water vapor barrier properties and the adhesive force, decreases the water content, and sufficiently suppresses the generation of outgases, so that consequently the service life of an element for organic electronic devices can be lengthened, and which gives a satisfactory external appearance when used to seal an organic electronic device; an element sealing resin sheet for organic electronic devices; an organic electroluminescent element; and an image display apparatus.

### Means for Solving Problem

In order to solve the problems described above, an element sealing resin composition for organic electronic devices according to the present invention contains a polyisobutylene resin (A) having a weight average molecular weight (Mw) of 10,000 to 300,000, and a hydrogenated cyclic olefin-based polymer (B), has a water content according to the Karl-Fischer method of 500 ppm or less, and has an amount of outgas generation of 500 ppm or less when the composition is heated at 85° C. for 1 hour.

It is preferable that in the element sealing resin composition for organic electronic devices, the mass ratio (A):(B) of the polyisobutylene resin (A) having a weight average molecular weight (Mw) of 10,000 to 300,000 and the hydrogenated cyclic olefin-based polymer (B) is 90:10 to 20:80.

Furthermore, it is preferable that the hydrogenated cyclic olefin-based polymer is a hydride of a C5-based petroleum resin, a hydride of a C9-based petroleum resin, or a hydride of a petroleum resin obtainable by copolymerizing a C5-based petroleum resin and a C9-based petroleum resin.

Furthermore, it is preferable that the element sealing resin composition for organic electronic devices has a loss modulus at 60° C. of 100,000 Pa·sec or less.

Furthermore, it is preferable that the element sealing resin composition for organic electronic devices further includes an organometallic desiccant or a metal oxide-based desiccant.

Furthermore, it is preferable that the element sealing resin composition for organic electronic devices includes the organometallic desiccant or the metal oxide-based desiccant in an amount of 1 wt % to 50 wt % relative to the total weight.

Furthermore, it is preferable that the element sealing resin composition for organic electronic devices has a light transmittance of 85% or higher for light having a wavelength of 550 nm at a thickness of 0.1 mm.

Furthermore, in order to solve the problems described above, an element sealing resin sheet for organic electronic devices according to the present invention includes at least a sealing layer formed from the element sealing resin composition for organic electronic devices according to any one of the above-described items.

Furthermore, in order to solve the problems described above, an organic electroluminescent element according to the present invention is sealed by the element sealing resin composition for organic electronic devices according to any one of the above-described items.

Furthermore, an image display apparatus according to the present invention includes the organic electroluminescent element described above.

### Effect of the Invention

The element sealing resin composition for organic electronic devices and the element sealing resin sheet for organic electronic devices according to the present invention have sufficiently low water vapor barrier properties, can sufficiently suppress the generation of outgases, and also have sufficient peeling strength. Therefore, the resin composition and the resin sheet can lengthen the service life of an organic EL element. Furthermore, since the resin composition and the resin sheet also have satisfactory conformity to an adherend, they do not allow air bubbles entering between the resin composition or the resin sheet and the adherend when used to seal, and have excellent external appearance.

### BRIEF DESCRIPTION OF DRAWINGS

FIG. 1 is a cross-sectional view schematically illustrating the structure of an element sealing resin sheet for organic electronic devices related to an embodiment of the present invention;

FIG. 2 is a cross-sectional view schematically illustrating the structure of an image display apparatus which uses an element sealing resin sheet for organic electronic devices related to the embodiment of the present invention; and

FIGS. 3A-3D are explanatory diagrams for schematically describing the use of an element sealing resin sheet for organic electronic devices related to the embodiment of the present invention.

### MODE(S) FOR CARRYING OUT THE INVENTION

Hereinafter, an embodiment of the present invention is described in detail.

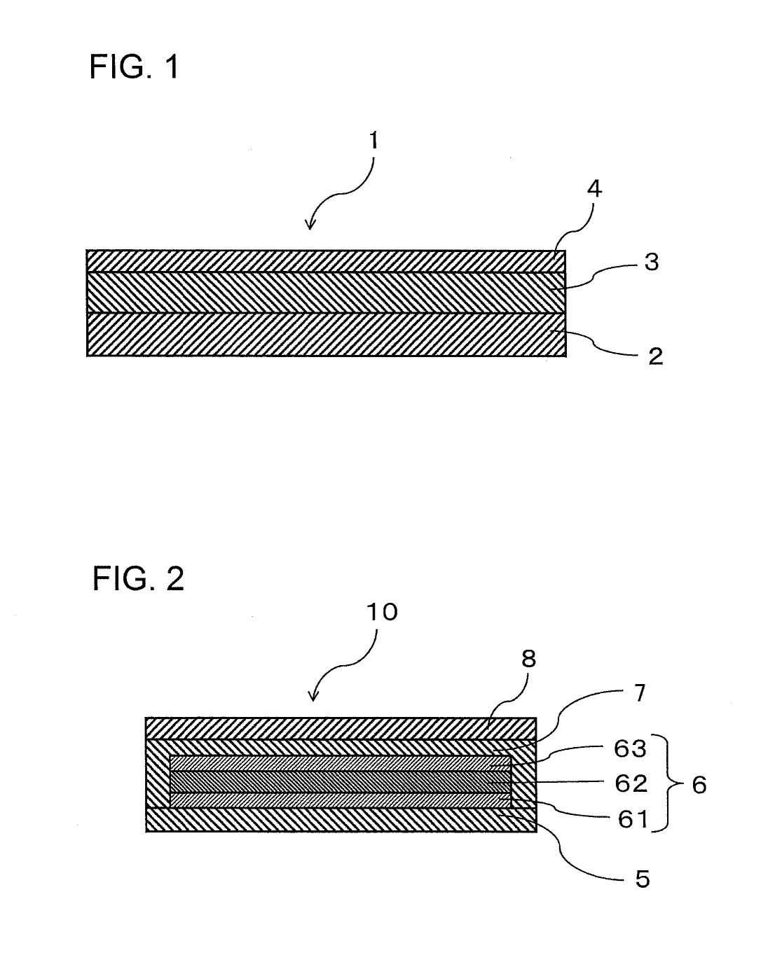

An element sealing resin sheet for organic electronic devices 1 related to the embodiment of the present invention has at least one sealing layer 3 on at least one side of a substrate sheet 2. FIG. 1 is an outline cross-sectional view illustrating a preferred embodiment of the element sealing resin sheet for organic electronic devices 1 of the present invention. As illustrated in FIG. 1, the element sealing resin sheet for organic electronic devices 1 has the substrate sheet 2, and the sealing layer 3 is formed on the substrate sheet 2. Also, the element sealing resin sheet for organic electronic devices 1 further includes a release film 4 for protecting the sealing layer 3, on the sealing layer 3.

Hereinafter, the various constituent elements of the element sealing resin sheet for organic electronic devices 1 of the present embodiment are described in detail.

(Substrate Sheet 2 and Release Film 4)

The substrate sheet 2 is intended to temporarily fix the resin composition for the purpose of improving handleability when the resin composition that constitutes the sealing layer 3 is made into a film form. Furthermore, the release film 4 is used for the purpose of protecting the sealing layer 3.

The substrate sheet 2 and the release film 4 are not particularly limited, and examples thereof include a polyethylene film, a polypropylene film, a polybutene film, a polybutadiene film, a polymethylpentene film, a polyvinyl chloride film, a vinyl chloride copolymer film, a polyethylene terephthalate film, a polyethylene naphthalate film, a polybutylene terephthalate film, a polyurethane film, an ethylene-vinyl acetate copolymer film, an ionomer resin film, an ethylene-(meth)acrylic acid copolymer film, an ethylene-(meth)acrylic ester copolymer film, a polystyrene film, a polycarbonate film, a polyimide film, and a fluororesin film. Furthermore, crosslinked films of these films are also used. Laminate films of these films may also be used. Particularly, in view of cost, handleability and the like, it is preferable to use polyethylene terephthalate.

In a release paper obtained by coating paper with a releasing agent, since water vapor passes through the paper substrate and reach the sealing layer 3, the sealing layer 3 absorbs moisture, moisture is transferred from the sealing layer 3 to the organic electronic device at the time of sealing, and thus deterioration of the organic electronic device is accelerated. Therefore, the release paper is not preferable as the substrate sheet 2 and the release film 4. Furthermore, a release paper obtained by coating paper with a releasing agent is also not preferable from the viewpoint that the amount of outgas generation is increased when heated at 85° C. for 1 hour.

The peeling force required when the sealing layer 3 is peeled off from the substrate sheet 2 and the release film 4 is, for example, preferably 0.3 N/20 mm or less, and more preferably 0.2 N/20 mm. There are no particular limitations on the lower limit of the peeling force; however, a peeling force of 0.005 N/20 mm or more is practical. Furthermore, when a peelable film is temporarily attached on both surfaces, it is preferable to use release films having different peeling forces in order to improve handleability.

The film thicknesses of the substrate sheet 2 and the release film 4 are usually 5 to 300 μm, preferably 10 to 200 μm, and particularly preferably about 20 to 100 μm.

(Sealing Layer 3)

The element sealing resin composition for organic electronic devices of the present invention that constitutes the sealing layer 3 contains a polyisobutylene resin (A) having a weight average molecular weight (Mw) of 10,000 to 300,000 and a hydrogenated cyclic olefin-based polymer (B), has a water content according to the Karl-Fischer method of 500 ppm or less, and has an amount of outgas generation of 500 ppm or less when heated at 85° C. for 1 hour.

[Polyisobutylene Resin (A)]

The polyisobutylene resin (A) is generally a resin having a polyisobutylene skeleton in the main chain or in a side chain, and any polyisobutylene resin can be used without any particular limitations as long as the resin has a weight average molecular weight (Mw) of 10,000 to 300,000. The polyisobutylene resin (A) is composed of a copolymer of an isobutylene monomer and one or more olefins as co-monomers, preferably conjugated olefins. The polyisobutylene resin is usually produced by a slurry method which uses methyl chloride as a medium and uses a Friedel-Crafts catalyst as a part of a polymerization initiator. Such a polyisobutylene resin has a feature of having high water vapor barrier properties and high adhesiveness.

Examples of the polyisobutylene resin (A) that is suitable for the present invention include GLISSOPAL and OPPANOL (B10, B12, B15, B50, B80, B100, B120, B150, B220, and the like) manufactured by BASF SE; TETRAX (3T, 4T, 5T, 6T and the like) and HIMOL (4H, 5H, 6H and the like) manufactured by JX Nippon Oil & Energy Corp.; and BUTYL RUBBER manufactured by Japan Butyl Co., Ltd. These may be used singly, or may be used in combination of two or more kinds after the viscosity is adjusted.

The polyisobutylene resin (A) has a weight average molecular weight (Mw) of 10,000 to 300,000. When the weight average molecular weight is larger, the water vapor barrier properties are increased, but the adhesive force to an adherend is decreased. When the weight average molecular weight is smaller, the adhesive force is increased, but the vapor barrier properties are decreased. Even though the water vapor barrier properties are high, when the adhesive force is excessively poor, water vapor or impurities penetrate through the gap between the sealing layer and the adherend unless a tight sealing treatment with glass frit is further carried out, and as a result, the element for organic electronic devices is prone to deterioration. Even though satisfactory adhesive force is achieved, when the vapor barrier properties are excessively low, water vapor permeates through the sealing layer even if the penetration of water vapor and the like through the gap is prevented. Thus, as a result, the element for organic electronic devices is prone to deterioration. Furthermore, if the weight average molecular weight is large, conformity to the adherend is decreased so that air bubbles enter between the sealing layer and the adherend when used for sealing, and the external appearance is impaired. When the average molecular weight (Mw) is adjusted to 10,000 to 300,000, since the water vapor barrier properties as well as the adhesive force are sufficient, deterioration of the element for organic electronic devices can be prevented. Furthermore, the sealing layer has satisfactory conformity to the adherend, and the external appearance is improved, without any air bubbles being entrained when the element for organic electronic devices is sealed.

Here, the weight average molecular weight (Mw) is a weight average molecular weight measured by gel permeation chromatography (GPC) using, for example, a GPC system manufactured by Waters Corp. (column: SHODEX K-804 (polystyrene gel) manufactured by Showa Denko K.K., mobile phase: chloroform), and calculated relative to polystyrene standards.

[Hydrogenated Cyclic Olefin-Based Polymer (B)]

Suitable examples of the hydrogenated cyclic olefin-based polymer include CLEARON P, M and K series manufactured by Yasuhara Chemical co., Ltd.; FORAL AX and 105 manufactured by Ashland, Inc.; ARKON P and M series, PENSEL A, ESTER GUM H, SUPER ESTER series, and PINECRYSTAL series manufactured by Arakawa Chemical Industries, Ltd.; I-MARV (P-100, P-125, and P-140) manufactured by Idemitsu Kosan Co., Ltd.; ESCOREZ (ESR, 5300, 5400, 5600 series) manufactured by Exxon Mobil Corp.; EASTOTAC series and FORAL series manufactured by Eastman Chemical Co. Among them, a hydride of a C5-based petroleum resin, a hydride of a C9-based petroleum resin, and a hydride of a petroleum resin obtainable by copolymerizing a C5-based petroleum resin and a C9-based petroleum resin are suitably used from the viewpoint of having satisfactory water vapor barrier performance and satisfactory transparency.

The number average molecular weight (Mn) according to a vapor pressure osmometry method (VPO method) of the hydrogenated cyclic olefin-based polymer (B) is suitably from 660 to 1000. If the number average molecular weight is less than 660, it is not preferable from the viewpoint that the heat-resistant temperature does not rise, and if the number average molecular weight is more than 1000, it is not preferable from the viewpoint that flexibility at the time of adhesion is damaged, and the function as a tackifying agent is impaired. Furthermore, the softening point according to JIS K 2207 is preferably from 100° C. to 150° C.

The mixing ratio (A):(B) of the polyisobutylene resin (A) having a weight average molecular weight (Mw) of 10,000 to 300,000 and the hydrogenated cyclic olefin-based polymer (B) is preferably 90:10 to 20:80, and particularly preferably 70:30 to 30:70, as a mass ratio. If the mixing ratio of the hydrogenated cyclic olefin-based polymer (B) is less than 10, adhesive force may be decreased, or brittleness is increased, so that pasting processability becomes poor when the sealing layer 3 is pasted to a glass substrate, an element substrate of an organic EL element, or the like. Furthermore, if the proportion of the polyisobutylene resin (A) having a weight average molecular weight (Mw) of 10,000 to 300,000 is less than 20, water permeability is increased, and the sealing layer cannot maintain the shape as a film and undergoes cracking or the like.

[Desiccant]

Furthermore, the element sealing resin composition for organic electronic devices may include a desiccant. The desiccant is used for the purpose of capturing moisture that permeates through the resin composition. When moisture is captured, moisture-induced deterioration of an element for organic electronic devices can be further suppressed.

The desiccant may be any of a metal oxide desiccant, or an organic desiccant, and there are no particular limitations. Also, the desiccant can be used singly or as a mixture of two or more kinds.

(Metal Oxide-Based Desiccant)

A metal oxide-based desiccant is usually added as a powder into a resin. The average particle size of the desiccant may be usually in the range of less than 20 μm, and is preferably 10 μm or less, and more preferably 1 μm or less. For example, powdered inorganic oxides such as barium oxide (BaO), calcium oxide (CaO), strontium oxide (SrO), magnesium oxide (MgO), zeolites, and Molecular Sieves (Union Showa K.K., trade name) can be used. As will be described below, in a case in which the element sealing resin composition for organic electronic devices is made into a film, the metal oxide-based desiccant should be made sufficiently smaller than the film thickness. When the particle size is adjusted as such, the possibility of damaging the organic EL element is reduced, and even in a case in which the element sealing resin composition is supplied to a device having a so-called top-emission structure, the desiccant particles do not interrupt image recognition. Incidentally, if the average particle size is less than 0.01 μm, the production cost may increase in order to prevent scattering of the desiccant particles.

(Organometallic Desiccant)

The organic compound may be any material which takes in water by a chemical reaction and is not opacified before and after the reaction. Particularly, an organometallic compound is suitably due to the desiccating ability. The organometallic compound according to the present invention is defined as a compound having a metal-carbon bond, a metal-oxygen bond, a metal-nitrogen bond, or the like. When water and an organometallic compound react with each other, the bonds described above are broken by a hydrolysis reaction, and a metal hydroxide is obtained.

Preferred examples of the organometallic compound according to the present invention include metal alkoxides, metal carboxylates, and metal chelates. Regarding the metal, any organometallic compound having high reactivity with water, that is, a metal atom whose various bonds between the aforementioned metal and an organic compound are easily broken by water, may be used. Specific examples thereof include aluminum, silicon, titanium, zirconium, silicon, bismuth, strontium, calcium, copper, sodium, and lithium. Further examples include magnesium, barium, vanadium, niobium, chromium, tantalum, tungsten, chromium, indium, and iron. Particularly, a desiccant of an organometallic compound having aluminum as the central metal is suitable from the viewpoints of dispersibility in the resin and reactivity with water. Examples of the organic group include alkoxy groups and carboxyl groups containing unsaturated hydrocarbons, saturated hydrocarbons, branched unsaturated hydrocarbons, branched saturated hydrocarbons, and cyclic hydrocarbons, such as a methoxy group, an ethoxy group, a propoxy group, a butoxy group, a 2-ethylhexyl group, an octyl group, a decyl group, a hexyl group, an octadecyl group, and a stearyl group; and β-diketonato groups such as an acetylacetonato group and a dipivaloylmethanato group.

The amount of addition of the desiccant is preferably 1 wt % to 50 wt % relative to the total weight of the element sealing resin composition for organic electronic devices. If the amount of addition is less than 1 wt %, the effect of the desiccant is not manifested, and if the amount of addition is 50 wt % or more, fluidity of the element sealing resin composition for organic electronic devices is decreased, and sealing is made difficult.

[Plasticizer]

Furthermore, the element sealing resin composition for organic electronic devices may include a plasticizer. Fluidity can be modified by introducing a plasticizer. Examples of the plasticizer include waxes, paraffins, esters such as phthalic acid esters and adipic acid esters, low molecular weight polybutene, and polyisobutylene.

[Other Additives]

The element sealing resin composition for organic electronic devices may include a silane coupling agent. When a silane coupling agent is used, the amount of chemical bonding to the adherend is increased, and the adhesion characteristics are enhanced.

Specific examples of the silane coupling agent include silane coupling agents such as 3-glycidoxypropyltrimethoxysilane, 3-glycidoxypropylmethyldimethoxysilane, 3-glycidoxypropylmethyldimethoxysilane, 2-(3,4-epoxycyclohexyl)ethyltrimethoxysilane, N-phenyl-γ-aminopropyltrimethoxysilane, N-(2-aminoethyl)-3-aminopropylmethyldimethoxysilane, N-(2-aminoethyl)-3-aminopropylmethyltrimethoxysilane, 3-aminopropyltriethoxysilane, 3-mercaptopropyltrimethoxysilane, vinyltrimethoxysilane, N-(2-(vinylbenzylamino)ethyl)-3-aminopropyltrimethoxysilane hydrochloride, and 3-methacryloxypropyltrimethoxysilane. These silane coupling agents may be used as mixtures of two or more kinds thereof. The content of the silane coupling agent is preferably 0.05 to 10 parts by mass, and more preferably 0.1 to 1 part by mass, relative to 100 parts by mass of the resin composition.

According to the present invention, as long as the purpose of the present invention is achieved, other components, for example, a storage stabilizer, an oxidation inhibitor, a tack adjusting agent, and a resin stabilizer can be further added to the resin composition; however, since there is a possibility that visibility of the image display apparatus may be deteriorated by the moisture or impurities present in those additive components, caution should be taken.

The element sealing resin composition for organic electronic devices has a water content according to the Karl-Fischer method, which is based on the moisture vaporization-coulometric titration method defined in JIS K 0068, is 500 ppm or less. When the water content according to the Karl-Fischer method is 500 ppm or less, deterioration of the element for organic electronic devices that has been sealed can be sufficiently delayed.

In order to adjust the water content according to the Karl-Fischer method of the element sealing resin composition for organic electronic devices to 500 ppm or less, the moisture, solvent, and volatile organic molecules in the resin composition may be eliminated with a dryer such as a conical dryer or an evaporator, and with a drying furnace in the case of having the resin composition processed into a film form. Incidentally, in order to prevent the element sealing resin composition for organic electronic devices from absorbing moisture in air during storage and causing an increase in the water content, the resin composition may be filled in an aluminum laminate bag having a water vapor permeability according to JIS Z 0222 of 0.1 g/(m²·d) or less, and this bag may be sealed in another bag together with a desiccant such as silica gel, calcium oxide or calcium chloride, and stored. Alternatively, the element sealing resin composition for organic electronic devices after the removal of moisture or the like may be filled and sealed in a glass bottle, a plastic bottle, a metal can or the like, and this may be sealed in an aluminum laminate bag having a water vapor permeability according to JIS Z 0222 of 0.1 g/(m²·d) or less, together with a desiccant such as silica gel, calcium oxide or calcium chloride, and stored.

The element sealing resin composition for organic electronic devices has an amount of outgas generation of 500 ppm or less when the resin composition is heated at 85° C. for 1 hour, which is measured by the gas chromatographic analysis method defined in JIS K 0114. When the amount of outgas generation is adjusted to 500 ppm or less, deterioration of the sealed element for organic electronic devices can be sufficiently suppressed. In order to adjust the amount of outgas generation to 500 ppm or less, the moisture, solvent, and volatile organic molecules in the resin composition may be eliminated with a dryer such as a conical dryer or an evaporator, and with a drying furnace in the case of having the resin composition processed into a film form. Incidentally, the resin composition may be filled in an aluminum laminate bag, and this bag may be sealed in another bag together with a desiccant such as silica gel, calcium oxide or calcium chloride, and stored. Alternatively, the resin composition after the removal of the solvent or the like may be filled and sealed in a glass bottle, a plastic bottle, a metal can or the like, and this may be sealed in an aluminum laminate bag together with a desiccant such as silica gel, calcium oxide, calcium chloride or the like, and stored.

The element sealing resin composition for organic electronic devices is preferably such that the loss modulus at 60° C. measured by ARES is 100,000 Pa·sec or less. If the loss modulus is larger than 100,000 Pa·sec, fluidity of the resin is decreased, and conformity to the surface unevenness of the sealing surface is decreased. Therefore, when a sealing substrate and an element substrate of the element for organic electronic devices are sealed with this element sealing resin composition for organic electronic devices, the external appearance of the pasting surface may be deteriorated.

It is preferable that the element sealing resin composition for organic electronic devices is colorless and transparent in the visible region at 400 to 800 nm, and it is preferable that the resin composition has a light transmittance of 85% or more for light having a wavelength of the 550 nm at a thickness of 0.1 mm. It is because if the light transmittance at 550 nm is less than 85%, visibility is decreased. The light transmittance can be selected by appropriately selecting the resin.

The resin composition for sealing an organic EL element may include a solvent when a film-like sealing layer 3 is obtained. Examples of such a solvent include organic solvents such as toluene, methyl ethyl ketone (MEK), ethyl acetate, dimethylacetamide, N-methyl-2-pyrrolidone, and mixed solutions thereof, and methyl ethyl ketone and toluene are particularly preferred. The individual materials included in the resin composition are mixed and dispersed in such a solvent, and a resin solution thus obtained is applied on the release surface of a substrate sheet 2 directly or by transfer according to a generally known method such as a roll coating method, a gravure coating method, a reverse coating method, a spray coating method, an air knife coating method, a curtain coating method, a die coating method, or a comma coating method, and dried. Thus, a sealing layer 3 can be obtained.

Furthermore, regarding a technique for obtaining a film-like sealing layer 3 without using an organic solvent, the sealing layer 3 can be obtained by melting the resin composition for sealing an organic EL element at a high temperature, extruding the composition by a generally known technique such as a hot melt coater, and then cooling the resin composition.

The thickness of the sealing layer 3 is not particularly limited, and the thickness can be appropriately selected in accordance with the applications. The thickness is usually 10 to 30 μm, and preferably 15 to 25 μm. If the thickness is less than 10 μm, sufficient adhesive strength may not be obtained, and if the thickness is more than 30 μm, since the area of the lateral surface of the sealed material that is exposed to air after sealing is enlarged, the amount of water absorption at the lateral surface is increased. Thus, high cost is required compared with the performance.

Furthermore, it is more preferable that the surface roughness Ra values of both the sealing layer 3 and the object of pasting to be brought into contact with the sealing layer 3, are 2 μm or less. When this surface roughness is more than 2 μm, even if the conformity of the resin composition for sealing an organic EL element itself is high, the possibility that the sealing layer 3 may not conform to the surface of the object of pasting is increased. For this reason, when the surface roughness is in an appropriate range, the sealing layer 3 adheres to the object of pasting, and therefore, visibility is increased. The surface roughness of the object of pasting can be changed by polishing or a surface treatment, and the surface roughness of the sealing layer 3 can be modified by changing the surface roughness of the cooling roll when the sealing layer is formed into a film form, or by changing the surface roughness of the release film 4.

The element sealing resin sheet for organic electronic devices 1 may have two or more layers of the sealing layer 3, or may have a layer other than the sealing layer 3. Regarding the layer other than the sealing layer 3, for example, a gas barrier film, a glass plate, a metal plate, a metal foil or the like may be compressed and laminated on the surface on the opposite side of the substrate sheet 2 of the sealing layer 3. In this case, the release film 4 may not be provided.

<Method of Use>

Next, the method of using the element sealing resin sheet for organic electronic devices 1 is described.

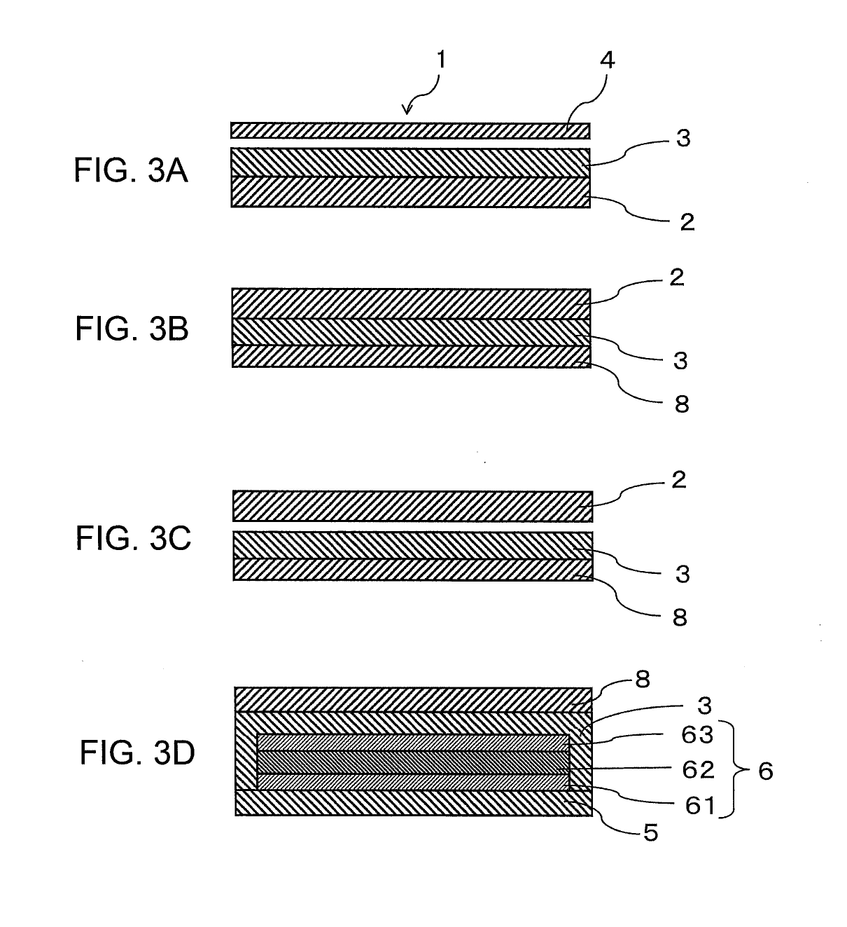

The element sealing resin sheet for organic electronic devices 1 of the present invention is used to seal an element for organic electronic devices such as an organic EL element 6. More specifically, the element sealing resin sheet 1 for organic electronic devices is used to obtain various organic electronic devices having a solid adhesion sealing structure by providing the resin sheet between an element for organic electronic devices such as an organic EL element 6 provided on an element substrate 5 (see FIGS. 2 and 3D) and a sealing substrate 8 (see FIGS. 2 and 3B˜3D), and tightly sealing the element for organic electronic devices with the element substrate 5 and the sealing substrate 8. Examples of the organic electronic device include an organic EL display, an organic EL lighting, an organic semiconductor, and an organic solar cell.

Hereinafter, an organic EL display (image display apparatus) is described as an example of the organic electronic device. In the organic EL display 10, as illustrated in FIG. 2, the organic EL element 6 provided on the element substrate 5 is sealed by the sealing substrate 8, with the resin layer for sealing an organic EL element 7 being interposed therebetween.

The organic EL element 6 includes, for example, as illustrated in FIG. 2, an anode 61 formed by patterning a conductive material, an organic layer 62 formed by a thin film of an organic compound material and laminated on the surface of the anode 61, and a cathode 63 laminated on the surface of the organic layer 62 and formed by patterning a transparent conductive material, on an element substrate 5 formed from a glass substrate or the like. Meanwhile, parts of the anode 61 and the cathode 63 protrude from an edge of the element substrate 5 and are connected to a driving circuit that is not illustrated in the diagram. The organic layer 62 is formed by laminating a hole injection layer, a hole transport layer, a light emitting layer, and an electron transport layer in this order from the anode 61 side, and the light emitting layer is formed by laminating a blue light emitting layer, a green light emitting layer, and a red light emitting layer. Meanwhile, the light emitting layer may also have non-luminescent intermediate layers between the various light emitting layers of blue, green and red colors.

Incidentally, in this organic EL display 10, the sealed lateral surface is exposed, and a further tight sealing treatment with glass frit or the like may not be needed. Since the element sealing resin composition for organic electronic devices according to the present invention has both high water vapor barrier properties and adhesiveness, it is not necessary to carry out a tight sealing treatment based on glass frit or the like as such, the structure of the organic electronic device is simplified, and the cost can be decreased.

For the sealing substrate 8, any material having properties that do not significantly inhibit visibility of the contents displayed by the organic EL display 10, may be used, and for example, glass or a resin can be used.

The resin layer for sealing an organic EL element 7 is formed using the element sealing resin sheet for organic electronic devices 1 described above, and the resin layer can be formed by the following procedure. First, as illustrated in FIG. 3A, the release film 4 of the element sealing resin sheet for organic electronic devices 1 is peeled off, and as illustrated in FIG. 3B, the sealing layer 3 is roll-pasted to the sealing substrate 8. Next, as illustrated in FIG. 3C, the substrate sheet 2 of the element sealing resin sheet for organic electronic devices 1 pasted to the sealing substrate 8 is peeled off. Thereafter, as illustrated in FIG. 3D, the sealing layer 3 of the element sealing resin sheet for organic electronic devices 1 pasted to the sealing substrate 8 is laminated on the cathode 63 side of the organic EL element 6. The sealing layer 3 of the element sealing resin sheet for organic electronic devices 1 constitutes the resin layer for sealing an organic EL element 7 in the organic EL display 10.

It is preferable that the pasting and lamination described above are carried out at a temperature of 100° C. or lower. If the temperature exceeds 100° C., the constituent materials of the organic EL element 6 are deteriorated, and there is a risk that the light emission characteristics may be deteriorated.

Incidentally, in the step for forming the resin layer for sealing an organic EL element 7 as described above, the element sealing resin sheet for organic electronic devices 1 is initially roll-pasted to the sealing substrate 8; however, it is also acceptable to produce a sealing layer 3-attached organic EL element by pasting the resin sheet 1 to the organic EL element 6. In this case, the substrate sheet 2 of the element sealing resin sheet for organic electronic devices 1 is peeled off, and then the sealing layer 3 is laminated on the sealing substrate 8.

Furthermore, a gas barrier film may be interposed between the sealing layer 3 and the sealing substrate 8, and an element sealing resin sheet for organic electronic devices 1 having a gas barrier film laminated in advance on the surface on the opposite side of the substrate sheet 2 of the sealing layer 3, may also be used. In the case of using the element sealing resin sheet for organic electronic devices 1 having a gas barrier film laminated in advance on the surface on the opposite side of the substrate sheet 2 of the sealing layer 3, a gas barrier film- and sealing layer 3-attached organic EL element is produced by peeling off the substrate sheet 2, and then pasting the sealing layer 3 to the organic EL element 6.

Hereinafter, the configuration of the present invention is described in more detail by way of Examples, but the present invention is not intended to be limited to these.

(Raw Materials)

<Polyisobutylene Resin>

A1: Weight average molecular weight 2,300 (BASF SE, GLISSOPAL V1500)

A2: Weight average molecular weight 36,000 (BASF SE, OPPANOL B10SFN)

A3: Weight average molecular weight 285,000 (manufactured by BASF SE, OPPANOL B30SF)

A4: Weight average molecular weight 800,000 (BASF SE, OPPANOL B80)

<Hydrogenated Cyclic Olefin-Based Polymer>

B1: Hydrogenated petroleum resin, softening point 100° C. (manufactured by Idemitsu Kosan Co., Ltd., I-MARV (registered trademark) P-100)

B2: Hydrogenated petroleum resin, softening point 140° C. (manufactured by Idemitsu Kosan Co., Ltd., I-MARV (registered trademark) P-140)

B3: C9-based hydrogenated petroleum resin, softening point 95° C. (manufactured by Arakawa Chemical Industries, Ltd., PINECRYSTAL KE311)

<Acrylic Resin>

C1: Weight average molecular weight 500,000 (manufactured by Nagase ChemteX Corp., SG-790)

<Desiccant>

D1: Calcium oxide (Wako Pure Chemical Industries, Ltd.)

D2: Magnesium oxide, average particle size 3.5 μm (manufactured by Konoshima Chemical Co., Ltd., STARMAG U)

D3: Organometallic compound (manufactured by Hope Chemical Co., Ltd., CHELOPE EP-2)

D4: Organometallic compound (manufactured by Kawaken Fine Chemicals Co., Ltd., ALCH-TR)

D5: Hydrophobized synthetic silicon dioxide, average particle size 1.4 μm (manufactured by Fuji Silysia Chemical Co., Ltd., trade name SYLYSIA 310)

### Example 1

With respect to 40 parts by weight of a polyisobutylene resin having a weight average molecular weight of 285,000 (manufactured by BASF SE, OPPANOL B30SF) as a polyisobutylene resin (A), 20 parts by weight of a hydrogenated petroleum resin (manufactured by Idemitsu Kosan Co., Ltd., I-MARV (registered trademark) P-100, softening point 100° C.) as a hydrogenated cyclic olefin-based polymer (B) was dissolved in 200 parts by weight of toluene, and thus a transparent coating liquid was obtained. Subsequently, the coating liquid was applied using an applicator over the entire surface of the release-treated surface of a silicone-based releasing agent-coated polyester film (manufactured by Mitsui Chemicals Tohcello, Inc., SP-PET-03) having a thickness of 38 μm as a substrate sheet such that the film thickness after drying would be 30 μm, and then the coating liquid was dried in a drying oven at 120° C. for 2 minutes. Thus, a sealing layer was formed. On the sealing layer thus obtained, a silicone-based release agent-coated polyester film (manufactured by Mitsui Chemicals Tohcello, Inc., SP-PET-01) having a thickness of 38 μm as a release film was laminated by means of the release-treated surface of polyester film. Thus, an element sealing resin sheet for organic electronic devices related to Example 1 was produced.

### Examples 2 to 9

Element sealing resin sheets for organic electronic devices related to Examples 2 to 7 and 9 were produced in the same manner as in Example 1, except that the coating liquids were prepared at the mixing compositions indicated in Table 1. Incidentally, the calcium oxide used in Example 8 was used in the coating liquid after being introduced into a mortar together with toluene in an amount capable of sufficiently immersing the calcium oxide, and ground to be sufficiently fined down. The magnesium oxide used in Example 7 was used directly because the particle size was sufficiently small.

### Comparative Examples 1 to 8

Element sealing resin sheets for organic electronic devices related to Comparative Examples 1 to 3 and 5 to 8 were produced in the same manner as in Example 1, except that the coating liquids were prepared at the mixing compositions indicated in Table 2. Furthermore, an element sealing resin sheet for organic electronic devices related to Comparative Example 4 was produced in the same manner as in Example 1, except that the coating liquid was prepared at the mixing composition indicated in Table 2, and the drying in a drying oven was carried out at 80° C. for 2 minutes.

(Evaluation Methods)

Evaluations were carried out according to the following evaluation methods. The results are presented in Table 1 and Table 2.

After the production, each of the element sealing resin sheets for organic electronic devices related to Examples 1 to 9 and Comparative Examples 1 to 8 was enveloped in an aluminum laminate bag (manufactured by Yutaka Finepack Co., Ltd., ST-678) having a moisture permeability of 0.1 g/m²·day (40° C., humidity 90%), which was produced by superposing and laminating 15 μm of nylon, 15 μm of polyethylene, 7 μm of an aluminum foil, 15 μm of polyethylene, and 50 μm of polyethylene, together with calcium chloride, and the resin sheet was stored in a vacuum sealed state, until various tests were carried out.

<Measurement of Water Content>

For the sealing layer of each of the element sealing resin sheets for organic electronic devices related to Examples and Comparative Examples with the release film and the substrate sheet being removed therefrom, the water content was measured by the Karl-Fischer method, which is based on the moisture vaporization-coulometric titration method defined in JIS K 0068. The set heating temperature was 150° C.

<Measurement of Amount of Outgases>

For the sealing layer of each of the element sealing resin sheets for organic electronic devices related to Examples and Comparative Examples with the release film and the substrate sheet being removed therefrom, measurement was performed by the gas chromatographic analysis method defined in JIS K 0114. The components volatilized when the sealing layer was heated at 85° C. for 1 hour were captured using a head space sampling apparatus, and were analyzed. Volatile components were determined relative to the amount of toluene.

<Measurement of Dynamic Viscoelasticity>

For the sealing layer of each of the element sealing resin sheets for organic electronic devices related to Examples and Comparative Examples with the release film and the substrate sheet being removed therefrom, a temperature variance analysis was carried out using a dynamic viscoelasticity apparatus (ARES apparatus, manufactured by Rheometric Scientific, Inc.) at a frequency of 0.1 Hz, a rate of temperature increase of 10° C./min, and an amount of strain of 0.3%, and the loss modulus G″ at 60° C. was determined.

<Measurement of Adhesive Force Against Glass>

The release film of the element sealing resin sheet for organic electronic devices related to each of Examples and Comparative Examples was peeled off, and an easy adhesion-treated polyester film (manufactured by DuPont Teij in Film, Ltd., TETORON FILM G2-C) having a thickness of 38 μm was roll-pasted at 80° C. thereto. This was used as a test specimen. The sealing layer side of the test specimen thus obtained was roll-pasted to an alkali-free glass for LCD (manufactured by Nippon Electric Glass Co., Ltd., OA-10G) having a thickness of 0.5 mm at a pasting temperature of 80° C., and the adhesive force was measured by the 180° peel test defined in JIS Z 0237.

<Glass Pasting Test (Appearance of Sealing)>

The release film of each of the element sealing resin sheets for organic electronic devices related to Examples and Comparative Examples was peeled off, and the sealing layer side was roll-pasted to an alkali-free glass for LCD (manufactured by Nippon Electric Glass Co., Ltd., OA-10G) having a thickness of 0.5 mm under the conditions of 60° C. and 0.1 MPa. Thereafter, the substrate sheet was peeled off, and the peeled surface was vacuum-pasted to a glass substrate under the conditions of 60° C. and 0.2 MPa for 2 seconds. Thus, a glass-attached sample was produced. For the glass-attached sample thus obtained, an evaluation of the appearance of sealing was carried out by visual inspection. A sample that did not contain air bubbles having a maximum width of 0.1 μm or more was considered to be a conforming product and was rated as “◯”; and a sample that contained air bubbles having a maximum width of 0.1 μm or more was considered to be a defective product and was rated as “X”.

<Evaluation of Service Life of Organic EL Element>

A commercially available ITO glass substrate was used, and etching was performed thereon while leaving electrode parts. Thereafter, the ITO glass substrate was subjected to ultrasonic washing at 45° C. for 10 minutes and UV ozone washing. Subsequently, an organic layer and a cathode were formed using a vacuum deposition machine, and an organic EL element that measured 19 mm on each side was produced. The organic EL element was configured to include glass substrate/ITO (300 nm)/NPB (30 nm)/Alq3 (40 nm)/Al—Li (40 nm)/Al (100 nm). Subsequently, the release film of each of the element sealing resin sheets for organic electronic devices related to Examples and Comparative Examples was peeled off, and the sealing layer side was pasted to an aluminum foil (manufactured by Mitsubishi Aluminum Co., Ltd., Mitsubishi Foil Tough) having a thickness of 17 μm. Thereafter, the substrate sheet was peeled off, the sealing layer surface was disposed on the surface of the cathode of an organic EL element, and the assembly was pressed for 1 minute at a pressure of 0.1 MPa at 80° C. Thus, an organic EL display model was produced. For the model thus produced, the half-life (unit: hour (hr)) by which the initial luminance is reduced to a half was determined at a current amount of 2 mA, using an organic EL luminescence efficiency analyzer (EL1003, manufactured by Precise Gauges Co., Ltd.). As a result, it was found that the present invention has excellent effects.

<Method for Measuring Light Transmittance>

Light transmittance can be determined by measuring the amount of transmitted light using a spectrophotometer (manufactured by Hitachi High-Technologies Corp., Photometer U-4100 type solid sample analysis system). The release film on one side of each of the element sealing resin sheets for organic electronic devices related to Examples and Comparative Examples was peeled off, the resin sheet was pasted to an alkali-free glass for LCD (manufactured by Nippon Electric Glass Co., Ltd., OA-10G) having a thickness of 0.5 mm at a pasting temperature of 80° C., and then the release film on the other side was peeled off. This was used as a measurement sample, and measurement was carried out using the same alkali-free glass for LCD as a reference.

TABLE 1

| | | Exam- | Exam- | Exam- | Exam- | Exam- | Exam- | Exam- | Exam- | Exam- |
|---|---|---|---|---|---|---|---|---|---|---|
| | | ple 1 | ple 2 | ple 3 | ple 4 | ple 5 | ple 6 | ple 7 | ple 8 | ple 9 |
| Polyisobutylene | A1 | | | | | | | | | |
| resin | A2 | | | | 20 | | | | | |
| [parts by weight] | A3 | 40 | 90 | 20 | | 40 | 40 | 40 | 40 | 40 |
| | A4 | | | | | | | | | |
| Hydrogenated cyclic | B1 | | 10 | 80 | 80 | 40 | 40 | 40 | 40 | 40 |
| olefin-based polymer | B2 | 40 | | | | | | | | |
| [parts by weight] | B3 | 20 | | | | 20 | 20 | 20 | 20 | 20 |
| Acrylic resin | C1 | | | | | | | | | |
| [parts by weight] | | | | | | | | | | |
| Desiccant | D1 | | | | | | | | 2 | |
| [parts by weight] | D2 | | | | | | | 30 | | |
| | D3 | | | | | | 100 | | | |
| | D4 | | | | | 1 | | | | |
| | D5 | | | | | | | | | 30 |

| | | | | | | | | | |
|---|---|---|---|---|---|---|---|---|---|
| Water content [ppm] | 300 | 300 | 300 | 300 | 300 | 100 | 200 | 300 | 200 |
| Amount of outgas generation [ppm] | 120 | 100 | 100 | 100 | 400 | 450 | 70 | 90 | 70 |
| Loss modulus @ 60° [Pa · sec] | 20000 | 10000 | 10000 | 2000 | 20000 | 20000 | 90000 | 30000 | 90000 |
| Adhesive force against | 17 | 10 | 15 | 15 | 20 | 10 | 10 | 16 | 10 |
| glass [N/25 mm] | | | | | | | | | |
| Appearance of pasting and | ◯ | ◯ | ◯ | ◯ | ◯ | ◯ | ◯ | ◯ | ◯ |
| sealing | | | | | | | | | |
| Service life of organic EL | 50 | 100 | 90 | 80 | 60 | 80 | 80 | 80 | 80 |
| element [hours] | | | | | | | | | |
| Light transmittance [%] | 98 | 97 | 96 | 97 | 96 | 95 | 70 | 88 | 90 |

TABLE 2

| | | Compar- | Compar- | Compar- | Compar- | Compar- | Compar- | Compar- | Compar- |
|---|---|---|---|---|---|---|---|---|---|
| | | ative | ative | ative | ative | ative | ative | ative | ative |
| | | Exam- | Exam- | Exam- | Exam- | Exam- | Exam- | Exam- | Exam- |
| | | ple 1 | ple 2 | ple 3 | ple 4 | ple 5 | ple 6 | ple 7 | ple 8 |
| Polyisobutylene | A1 | | 40 | | | | | | |
| resin | A2 | | | | | | | | |
| [parts by weight] | A3 | | | 40 | 40 | 5 | 95 | 40 | 40 |
| | A4 | 40 | | | | | | | |
| Hydrogenated cyclic | B1 | | 40 | 40 | 40 | 65 | 5 | 40 | 40 |
| olefin-based polymer | B2 | 60 | | | | | | | |
| [parts by weight] | B3 | | 20 | 20 | 20 | 30 | | 20 | 20 |
| Acrylic resin | C1 | | | 200 | | | | | |
| [parts by weight] | | | | | | | | | |
| Desiccant | D1 | | | | | | | | |
| [parts by weight] | D2 | | | | | | | 150 | |
| | D3 | | | | | | | | 150 |
| | D4 | | | | | 1 | | | |
| | D5 | | | | | | | | |

| | | | | | | | | |
|---|---|---|---|---|---|---|---|---|
| Water content [ppm] | 2000 | 3000 | 4000 | 600 | 300 | 300 | 100 | 100 |
| Amount of outgas generation [ppm] | 80 | 750 | 700 | 600 | 300 | 350 | 100 | 1500 |
| Loss modulus @ 60° [Pa · sec] | 20000 | 2000 | 1000 | 20000 | 10000 | 4000 | 1000000 | — |
| Adhesive force against | 9 | 7 | 10 | 20 | 7 | 5 | Pasting was | Pasting was |
| glass [N/25 mm] | | | | | | | not possible | not possible |
| Appearance of pasting and | X | ◯ | Clouding | ◯ | ◯ | ◯ | Pasting was | Pasting was |
| sealing | | | | | | | not possible | not possible |
| Service life of organic EL | 20 | 20 | 10 | 10 | 40 | 70 | — | — |
| element [hours] | | | | | | | | |
| Light transmittance [%] | Measuring | 95 | Measuring | 96 | 95 | 95 | Measuring | Measuring |
| | was not | | was not | | | | was not | was not |
| | possible | | possible | | | | possible | possible |

### EXPLANATIONS OF LETTERS OR NUMERALS

1: ELEMENT SEALING RESIN SHEET FOR ORGANIC ELECTRONIC DEVICES
2: SUBSTRATE SHEET
3: SEALING LAYER
4: RELEASE FILM
5: ELEMENT SUBSTRATE
6: ORGANIC EL ELEMENT
10: ORGANIC EL DISPLAY
61: ANODE
62: ORGANIC LAYER
63: CATHODE
7: RESIN LAYER FOR SEALING AN ORGANIC EL ELEMENT
8: SEALING SUBSTRATE

1. An element sealing resin composition for organic electronic devices, comprising a polyisobutylene resin (A) having a weight average molecular weight (Mw) of 10,000 to 300,000 and a hydrogenated cyclic olefin-based polymer (B), the resin composition having a water content according to the Karl-Fischer method of 500 ppm or less and an amount of outgas generation of 500 ppm or less when the resin composition is heated at 85° C. for 1 hour.

2. The element sealing resin composition for organic electronic devices according to claim 1, wherein the mass ratio (A):(B) of the polyisobutylene resin (A) having a weight average molecular weight (Mw) of 10,000 to 300,000 and the hydrogenated cyclic olefin-based polymer (B) is 90:10 to 20:80.

3. The element sealing resin composition for organic electronic devices according to claim 1, wherein the hydrogenated cyclic olefin-based polymer is a hydride of a C5-based petroleum resin, a hydride of a C9-based petroleum resin, or a hydride of a petroleum resin obtainable by copolymerizing a C5-based petroleum resin and a C9-based petroleum resin.

4. The element sealing resin composition for organic electronic devices according to claim 1, wherein the resin composition has a loss modulus at 60° C. of 100,000 Pa·sec or less.

5. The element sealing resin composition for organic electronic devices according to claim 1, further comprising an organometallic desiccant or a metal oxide-based desiccant.

6. The element sealing resin composition for organic electronic devices according to claim 5, wherein the organometallic desiccant or the metal oxide-based desiccant is included in an amount of 1 wt % to 50 wt % relative to the total weight.

7. The element sealing resin composition for organic electronic devices according to claim 1, wherein the resin composition has a light transmittance of 85% or higher for light having a wavelength of 550 nm at a thickness of 0.1 mm.

8. An element sealing resin sheet for organic electronic devices, comprising at least a sealing layer formed from the element sealing resin composition for organic electronic devices according to claim 1.

9. An organic electroluminescent element sealed by the element sealing resin composition for organic electronic devices according to claim 1.

10. An image display apparatus comprising the organic electroluminescent element according to claim 9.
